(19) United States
(12) Patent Application Publication
(10) Pub. No.: US 2026/0231589 A1
(43) Pub. Date: Aug. 6, 2026

(54) ULTRA-THIN SIDE-EMITTING LED PACKAGE STRUCTURE WITH BUILT-IN DRIVER IC DIE

(71) Applicant: Anhui Hoivway Optoelectronics Technology Co.,Ltd, Anqing (CN)

(72) Inventors: Chengying FANG, Anqing (CN); Deng ZHANG, Anqing (CN)

(21) Appl. No.: 19/466,502

(22) Filed: Feb. 1, 2026

(30) Foreign Application Priority Data
Dec. 17, 2025 (CN) 2025119063655

(51) Int. Cl. H10H 29/85; H10D 80/30; H10H 29/24; H10H 29/80

(52) U.S. Cl. CPC H10H 29/857; H10D 80/30; H10H 29/24; H10H 29/8421

(57) ABSTRACT

An ultra-thin side-emitting LED package structure with a built-in driver IC die includes a housing, a metal pad fixed inside the housing, and the driver IC die fixedly provided at a middle position of the metal pad, where the surface of the driver IC die is coated with a reflective coating, one side of the driver IC die is provided with RGB light-emitting dies fixedly provided on the metal pad, beveled reinforcement structures are provided at the die-bonding area of the surface of the metal pad, the beveled reinforcement structures at the left and right two sides of the driver IC die are symmetrically provided, and reinforcing protrusions are provided at positions of the inner wall of the housing near the edge of the metal pad.

### CROSS REFERENCE TO RELATED APPLICATIONS

The present disclosure claims the priority to the Chinese patent application with the filing No. 2025119063655, entitled “ULTRA-THIN SIDE-EMITTING LED PACKAGE STRUCTURE WITH BUILT-IN DRIVER IC” and filed on December 17, 2025 with the Chinese Patent Office, the contents of which are incorporated herein by reference in their entirety.

### TECHNICAL FIELD

The present disclosure relates to the technical field of LEDs, specifically to an ultra-thin side-emitting LED (light emitting diode) package structure with a built-in driver IC (integrated circuit) die.

### BACKGROUND ART

In application scenarios such as laptop keyboard backlighting, ambient light strips, and illuminated logo backlight source, frame-type side-emitting LED products are widely used due to their lightweight and thin characteristics. Currently, conventional frame-type side-emitting products on the market can only achieve white light side-emitting or basic RGB light emitting function, and cannot integrate built-in control IC dies, resulting in significant limitations in functional expansion of the product. Meanwhile, due to the strict thickness requirements of side-emitting products, existing frames have the following structural design defects: the strengths of the frame body and the packaged finished product are generally low, making them prone to breakage during transportation, assembly, or daily use, which seriously affects product reliability; and in addition, some side-emitting products attempting to integrate IC dies suffer from insufficient brightness issue, while traditional RGB side-emitting products generally suffer from the defect of poor color mixing uniformity due to unreasonable design of the light-emitting distance (i.e., color mixing distance) of three primary color dies, making it difficult to meet the high-quality requirements of high-end application scenarios for light efficiency and visual effects.

### SUMMARY

To address the shortcomings of the prior art, the present disclosure provides an ultra-thin side-emitting LED package structure with a built-in driver IC die, which solves the technical problems of existing conventional side-emitting LEDs that under the same thickness condition, the IC dies cannot be built therein and the strength of the frame is low, and the brightness is insufficient, and the color mixing uniformity is poor.

To solve the above-mentioned technical problems, the present disclosure provides the following technical solutions: an ultra-thin side-emitting LED package structure with a built-in driver IC die, including a housing, a metal pad fixed inside the housing, and the driver IC die fixedly provided at the middle position of the metal pad, where the surface of the driver IC die is coated with a reflective coating, one side of the driver IC die is provided with RGB light-emitting dies fixedly provided on the metal pad, beveled reinforcement structures are provided at the die-bonding area of the surface of the metal pad, and the beveled reinforcement structures at the left and right two sides of the driver IC die are symmetrically provided, reinforcing protrusions are provided at positions of the inner wall of the housing near the edge of the metal pad, and the reinforcing protrusions are provided offset from the die-bonding positions and the bonding wire positions.

Preferably, the RGB light-emitting dies are three primary color dies of R (red), G (green) and B (blue), where the three primary color dies of R, G and B are arranged sequentially in the same direction.

Preferably, the light-emitting distance (i.e., color mixing distance) of the three primary color dies of R, G, and B inside the housing is minimized.

Preferably, each of the reinforcing protrusions has the cross section in a shape of trapezoid, where the trapezoid has a short side abutting the edge of the metal pad and a long side connected to the inner wall of the housing, and the heights of the reinforcing protrusions are consistent with the thickness of the metal pad.

Preferably, the reflective coating is specifically a white silicone coating, for preventing occurrence of a light absorption phenomenon of the driver IC die made of a silicon-based or gallium arsenide material.

Preferably, the beveled reinforcement structures are each in a shape of one of: "/", "S", "L" or "T".

Preferably, portions of the inner wall of the housing closed to two ends are provided with bowl trough-shaped slopes (i.e., light-guiding and concentrating ramps), and the bowl trough-shaped slopes face the light-emitting direction of the RGB light-emitting dies (i.e., the concave surface of each of the bowl trough-shaped slopes faces the light exit surface of the RGB light-emitting dies).

Preferably, the bottom of the housing is provided with a plurality of recessed grooves, and the recessed grooves are provided therein with pins integrally formed with the metal pad, and the bottoms of the pins are flush with the bottom surface of the housing.

Preferably, a polarity notch mark is provided at one corner of the housing.

By means of the above technical solutions, the present disclosure provides an ultra-thin side-emitting LED package structure with a built-in driver IC die, which has at least the following beneficial effects.

1. By providing the beveled reinforcement structures at the die-bonding area of the surface of the metal pad and providing the reinforcing protrusions at positions of the inner wall of the housing near the edge of the metal pad, the present disclosure effectively disperses the loads generated by external force action, such as hand pressure-generated stress, solves the problems of low strength and proneness to body breakage of existing side-emitting LED product, significantly improves the resistance to damage of the product throughout its entire life cycle, extends the service life of the product, and reduces the cost of loss during transportation and use.

2. By pre-coating a layer of high-reflectivity white silicone coating material on the surface of the driver IC die, the present disclosure specifically addresses the light absorption problem of the driver IC die substrate of the silicon-based or gallium arsenide material, thereby maximizing the retention of LED luminous energy.

3. By fixing the RGB light-emitting dies to the same side of the metal pad and maximally shortening the light-emitting distance of the three primary color dies of R, G, and B inside the housing, the present disclosure ensures the full fusion and uniform superposition of the three colors of light from the structural design level, enabling the advantages of purer light color and higher uniformity, and can meet the needs of application scenarios with high visual effect requirements, such as ambient light strips and illuminated logos, and improve the user experience of terminal products.

### BRIEF DESCRIPTION OF DRAWINGS

The drawings illustrated here are provided to further understand the present disclosure, and constitute a part of the present application:

FIG. 1 is a schematic view of the overall structure of the present disclosure; and

FIG. 2 is a schematic view of the overall product thickness of the present disclosure.

Reference numerals:

1. housing; 2. metal pad; 3. driver IC die; 4. RGB light-emitting die; 5. beveled reinforcement structure; 6. reinforcing protrusion; 7. bowl trough-shaped slope; 8. recessed groove; 9. pin; 10. polarity notch mark.

### DETAILED DESCRIPTION OF EMBODIMENTS

The technical solutions of the embodiments of the present disclosure will be clearly and completely described below with reference to the drawings in the embodiments of the present application. Obviously, the described embodiments are only some embodiments of the present disclosure, not all embodiments. Based on the embodiments of the present disclosure, all other embodiments obtained by those ordinarily skilled in the art without paying creative effort shall fall within the scope of protection of the present disclosure.

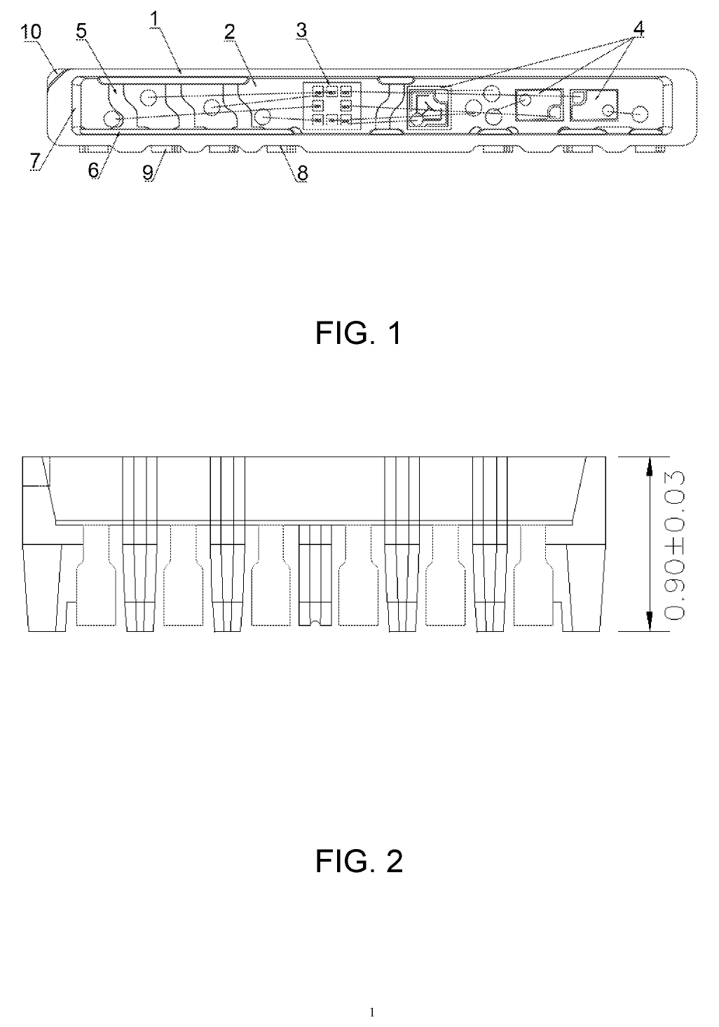

Based on the technical defects of the prior art that under the same thickness condition, the IC dies cannot be built therein and the strength of the frame is low, and the brightness is insufficient, and the color mixing uniformity is poor, referring to FIGS. 1-2, the embodiment provides an ultra-thin side-emitting LED package structure with a built-in driver IC die, which solves the industry problems of low strength and proneness to body breakage of existing side-emitting LED product, significantly improves the resistance to damage of the product throughout its entire life cycle, extends the service life of the product, reduces the cost of loss during transportation and use, and improves the luminous brightness and uniformity of the side-emitting LED product. The structure includes a housing 1, a metal pad 2 fixed inside the housing 1, and a driver IC die 3 fixedly provided at the middle position of the metal pad 2, where the surface of the driver IC die 3 is coated with a reflective coating, one side of the driver IC die 3 is provided with RGB light-emitting dies 4 fixedly provided on the metal pad 2, beveled reinforcement structures are provided at the die-bonding area of the surface of the metal pad 2, and the beveled reinforcement structures at the left and right two sides of the driver IC die 3 are symmetrically provided, reinforcing protrusions 6 are provided at positions of the inner wall of the housing 1 near the edge of the metal pad 2, and the reinforcing protrusions 6 are provided offset from the die-bonding positions and the bonding wire positions. By fixedly providing the driver IC die 3 in the middle of the metal pad 2, it achieves built-in IC in an ultra-thin structure, breaking through the functional limitations of existing products; the beveled reinforcement structures of the metal pad 2 and the reinforcing protrusions 6 on the inner wall of the housing 1 doubly enhance the structural strength of the frame body, solving the problem of proneness to breakage; the reflective coating on the surface of the driver IC die 3 can block the light absorption of the driver IC die 3, reducing light energy loss; and the reinforcing protrusions 6 are provided offset from the die bonding and bonding wire positions, to avoid affecting the core light-emitting and electrical connection functions, and ensure the normal operation of the product.

Existing RGB side-emitting products suffer from poor color mixing uniformity and insufficient color consistency due to the disordered arrangement and overlarge light-emitting distance of the three primary color dies. To address this issue, the RGB light-emitting dies 4 are three primary color dies of R, G, and B respectively, the three primary color dies of R, G, and B are arranged sequentially in the same direction, and the light-emitting distance of the three primary color dies of R, G, and B inside the housing 1 is minimized. This sequential arrangement of the three primary color dies of R, G, and B in the same direction and the minimized light-emitting distance shorten the three-color light fusion path at the structural level, ensuring uniform RGB color mixing and high color consistency and meeting the high-quality visual effect requirements of high-end backlighting and ambient light strips.

Existing side-emitting LED products lack reinforcement structures, and are prone to breakage during transportation, assembly, or daily use, which severely affects product reliability. To address this issue, the reinforcing protrusion 6 has a cross section in a shape of trapezoid, where the trapezoid has a short side abutting the edge of the metal pad 2 and a long side connected to the inner wall of the housing 1, and the height of the reinforcing protrusion 6 is consistent with the thickness of the metal pad 2. The trapezoidal cross-section of the reinforcing protrusion 6 maximally disperses external stress, further enhancing the resistance to damage of the frame; and the fact that the height of the reinforcing protrusion 6 is consistent with the thickness of the metal pad 2 enhances the strengthen of the product without increasing its overall thickness, ensuring the ultra-thin core characteristic.

Existing side-emitting LED products have not been optimized to address the light absorption problem of the driver IC die 3. The driver IC die 3 of the silicon-based or gallium arsenide material may absorb the light emitted by the LED, resulting in significant decrease in the brightness of the lamp beads. To address this issue, the reflective coating is specifically made of a white silicone coating material to prevent occurrence of the light absorption phenomenon of the driver IC die 3 of the silicon-based or gallium arsenide material. The reflective coating is defined as the white silicone coating material, whose high reflectivity enables the light absorption of the driver IC die 3 to be directly blocked, maximizing the retention of the light-emitting energy of the RGB light-emitting dies 4 and improving the side luminous intensity of the product.

Existing side-emitting LED products suffer from the problems of low strength and proneness to breakage. To address this issue, the beveled reinforcement structures are each in a shape of one of: "/", "S", "L", or "T". This embodiment only provides the "S" shape; other shapes may be adjusted as required in actual production. The aforementioned beveled shape enables the interwoven connection form formed between the metal pad 2 and the housing 1, to greatly improve the connection tightness of them, and disperses stress caused by external forces such as hand pressure and assembly, to solve the problem of fragile/weak frame from the structural root, and simultaneously provides multiple structural options to adapt to different production scenarios.

Existing side-emitting products lack optimized light exit paths and has dispersed side light intensity, resulting in insufficient overall brightness, and failing to meet the application requirements of high-brightness. To address this issue, portions of the inner wall of the housing 1 closed to two sides are provided with bowl trough-shaped slopes 7, and the bowl trough-shaped slopes 7 face the light-emitting direction of the RGB light-emitting dies 4, so as to guide and concentrate the light emitted by the RGB light-emitting dies 4, optimize the light exit angle and path, reduce scattering loss of side light, significantly improve the side luminous intensity of the product, and solve the problem of insufficient side light intensity. In one or more embodiments， the bowl trough-shaped slope 7 is a reflective cup which is injection-molded from polyphthalamide (PPA) plastic with high reflectivity and heat/light radiation resistance.

The design of pins 9 of the existing products easily increases the overall thickness, failing to meet the ultra-thin requirement, and the connection between the pins 9 and the metal pad 2 is loose, easily leading to electrical connection failures. To address this issue, multiple recessed grooves 8 are provided at the bottom of the housing 1, the recessed grooves 8 are provided therein with pins 9 integrally formed with the metal pad 2, and the bottoms of the pins 9 are flush with the bottom surface of the housing 1. The recessed grooves 8 accommodate the pins 9, and the bottoms of the pins 9 are flush with the bottom surface of the housing 1, ensuring that the overall product thickness meets the ultra-thin standard. Moreover, the integral forming of the pins 9 with the metal pad 2 improves the connection stability of them, guarantees reliable electrical connection, and reduces the risk of poor contact. In one or more embodiments, the pin 9 is special 7PIN.

Existing side-emitting products lack clear polarity mark, resulting in that it is easy to cause product malfunction during assembly due to incorrect polarity judgment and reduce assembly efficiency. To address this issue, a polarity notch mark 10 is provided at one corner of the housing 1. The polarity notch mark 10 at the one corner of the housing 1 can help assemblers quickly identify the positive and negative poles of the product, avoid incorrect polarity connection problem, reduce the installation error rate, and improve the operational efficiency during batch assembly.

It should be noted that the terms “comprising”, “including” or any other variations thereof are intended to cover non-exclusive inclusion, such that a process, method, article, or apparatus that comprises a list of elements includes not only those elements but also other elements not expressly listed, or further includes elements inherent to such process, method, article, or apparatus.

Although embodiments of the present disclosure have been shown and described, it will be understood by those ordinarily skilled in the art that various changes, modifications, substitutions and variations may be made to these embodiments without departing from the principles and spirit of the present disclosure, and the scope of the present disclosure is defined by the appended claims and their equivalents.

1. An ultra-thin side-emitting light emitting diode (LED) package structure with a built-in driver integrated circuit (IC) die, comprising a housing, a metal pad fixed inside the housing, and the driver IC die fixedly provided at a middle position of the metal pad, wherein a surface of the driver IC die is coated with a reflective coating, one side of the driver IC die is provided with RGB light-emitting dies fixedly provided on the metal pad, beveled reinforcement structures are provided at a die-bonding area of a surface of the metal pad, the beveled reinforcement structures at left and right two sides of the driver IC die are symmetrically provided, reinforcing protrusions are provided at positions of an inner wall of the housing near an edge of the metal pad, and the reinforcing protrusions are provided offset from die-bonding positions and bonding wire positions.

2. The ultra-thin side-emitting LED package structure with a built-in driver IC die according to claim 1, wherein the RGB light-emitting dies are three primary color dies of R, G and B respectively, and the three primary color dies of R, G and B are arranged sequentially in a same direction.

3. The ultra-thin side-emitting LED package structure with a built-in driver IC die according to claim 2, wherein a light-emitting distance of the three primary color dies of R, G and B inside the housing is minimized.

4. The ultra-thin side-emitting LED package structure with a built-in driver IC die according to claim 1, wherein each of the reinforcing protrusions has a cross section in a shape of trapezoid, the trapezoid has a short side abutting the edge of the metal pad and a long side connected to the inner wall of the housing, and heights of the reinforcing protrusions are consistent with a thickness of the metal pad.

5. The ultra-thin side-emitting LED package structure with a built-in driver IC die according to claim 1, wherein the reflective coating is specifically of a white silicone coating material, and configured to prevent occurrence of a light absorption phenomenon of the driver IC die of a silicon-based or gallium arsenide material.

6. The ultra-thin side-emitting LED package structure with a built-in driver IC die according to claim 1, wherein the beveled reinforcement structures are each in a shape of one of "/", "S", "L" or "T".

7. The ultra-thin side-emitting LED package structure with a built-in driver IC die according to claim 1, wherein portions of the inner wall of the housing closed to two ends are provided with bowl trough-shaped slopes, and the bowl trough-shaped slopes face a light-emitting direction of the RGB light-emitting dies.

8. The ultra-thin side-emitting LED package structure with a built-in driver IC die according to claim 1, wherein a bottom of the housing is provided with a plurality of recessed grooves, the recessed grooves are provided therein with pins integrally formed with the metal pad, and bottoms of the pins are flush with a bottom surface of the housing.

9. The ultra-thin side-emitting LED package structure with a built-in driver IC die according to claim 1, wherein a polarity notch mark is provided at one corner of the housing.
